(19) United States
(12) Patent Application Publication
(10) Pub. No.: US 2014/0023856 A1
(43) Pub. Date: Jan. 23, 2014

(54) COAT AS WELL AS METHOD AND DEVICE FOR COATING

(71) Applicants: Eckart GmbH, Hartenstein (DE); Reinhausen Plasma GmbH, Regensburg (DE)

(72) Inventors: Michael Bisges, Regensburg (DE); Christian Wolfrum, Erlangen (DE); Marco Greb, Gelnhausen (DE); Markus Rupprecht, Edelsfeld (DE)

(21) Appl. No.: 14/027,738

(22) Filed: Sep. 16, 2013

Related U.S. Application Data
(63) Continuation of application No. PCT/EP2012/054530, filed on Mar. 15, 2012.

(30) Foreign Application Priority Data
Mar. 16, 2011 (DE) 102011001312.1
Apr. 12, 2011 (DE) 102011001982.0

(51) Int. Cl. C23C 16/50; C23C 16/06

(52) U.S. Cl. CPC C23C 16/50; C23C 16/06
USPC 428/329; 427/569; 118/723 E; 427/576; 428/328

(57) ABSTRACT

The invention relates to a method and a device for applying a coating to a substrate, where a plasma jet of a low-temperature plasma is produced by conducting a working gas through an excitation zone. The plasma jet is directed at the substrate, and plate-shaped particles having an average thickness between 10 and 50,000 nanometers and a shape factor in a value range from 10 to 2000 are fed into the plasma jet. The plate-shaped particles are fed into the plasma jet by means of a carrier gas. The plasma jet is produced by exciting the working gas by means of an alternating voltage or a pulsed direct voltage.

### CROSS-REFERENCE TO RELATED APPLICATIONS

This application is filed under 35 U.S.C. §120 and §365(c) as a continuation of International Patent Application PCT/EP2012/054530, filed Mar. 15, 2012, which application claims priority from German Patent Application No. 10 2011 001 312.1, filed Mar. 16, 2011 and from German Patent Application No. 10 2011 001 982.0, filed Apr. 112, 2011, which applications are incorporated herein by reference in their entireties.

### FIELD OF THE INVENTION

The present invention concerns a method and a device for the application of a coat onto a substrate, in which a plasma beam of a low temperature plasma is generated by leading a working gas through an excitation zone.

In addition, the invention concerns a coat on a substrate made up of platelet-shaped particles that are at least partially fused with one another, as well as the use of platelet-shaped particles.

### BACKGROUND OF THE INVENTION

The generation of layers on substrates has been known for a long time and is of high economical interest. A plurality of different methods are used, which partially condition reduced pressure due to the processing technique, very high speeds or high temperatures.

A known method is plasma spraying, in which a gas or gas mixture flowing through an electric arc of a plasma burner is ionized. During the ionization, a highly heated up, electrically conductive gas with a temperature of up to 20,000 K is generated. In this plasma beam, powder, usually with a grain distribution between 5 to 120 μm, is injected, which powder is molten on due to the high plasma temperature. The plasma beam carries along the powder particles and applies them onto the substrate to be coated. Plasma coating by way of plasma spraying can be performed under normal atmosphere.

The high gas temperatures of more than 10,000° C. are required in order to melt on the powder, and thus, be able to deposit is as a layer. Accordingly, plasma spraying is very demanding in terms of energy, where a cost-effective coating of substrate is often not possible. In addition, complex apparatus must be used for generation of the high temperatures. Due to the high temperatures, temperature-sensitive and/or very thin substrates, like polymer films and/or paper, cannot be coated. Due to the high thermal energy, damages are caused to such substrates. Partly, elaborate pre-treatment steps are required in order to ensure a sufficient adhesion of the deposited layer on the surface. Additionally, it is disadvantageous that the particles used are subject to a high thermal load during plasma spraying, where the particles can oxidize at least partially, for example, when using metallic particles. For example, it is disadvantageous if metallic layers are intended to be deposited for use, for example, for conductor tracks or as corrosion protection.

For these reasons, methods were developed, which use a so-called atmospheric cold plasma, also designated as low temperature plasma, in order to generate layers on substrates. In these methods, methods known to those skilled in the art are applied to generate a cold plasma beam under atmospheric conditions and to insert a powder into the plasma beam, which powder is subsequently deposited onto the substrate.

European Patent No. 1 230 414 B1 describes a generic method for application of a coat onto a substrate, in which a plasma beam of a low temperature plasma is generated by leading the working gas through an excitation zone under atmospheric conditions. A precursor material consisting of monomer compounds is supplied into the plasma beam separate from the working gas. For sensitive precursor materials, the supply into the relatively cool plasma beam can take place downstream of the excitation zone. Through this, coating of the substrate with precursor materials, which are stable only at temperatures of up to 200 degrees Celsius or less, is possible.

The disadvantages of this method are that monomer compounds are supplied as precursor materials into a plasma, and brought there to a reaction, where only relative low deposition rates of 300-400 nm/s can be achieved. Compared with the deposition rates, which are achieved in appropriate methods with pulverulent starting materials, these are lower by the factor 10-1000, even when using particles, which are available in the order of magnitude of 100 μm. Accordingly, an economical coating in the industrial scale is not possible with this method.

European Patent No. 1 675 971 B1 describes a further method for coating of a substrate surface using a plasma beam of a low temperature plasma into which a fine-grained powder forming the coating is supplied with a size of 0.001-100 μm by means of a powder conveyor. By way of derogation from the thermal plasmas, the temperature of a low temperature plasma reaches less than 900° C. in the core of the plasma beam at ambient pressure. For thermal plasmas, nevertheless, temperatures of up to 20,000° C. in the core of the occurring plasma beam are indicated in European Patent No. 1 675 971 B1.

It is disadvantageous that powder from materials with higher melting points, for example, ceramic materials or highly melting metals, cannot be molten on in the process. The speed of the plasma beam is so high that the dwell time of the small particles of the powder in the hot zones of the plasma is not sufficient in order to reach a fill melting-through of the particles. For materials with increased melting temperatures (e.g., Ag, Cu, Ni, Fe, Ti, W), melting-on therefore occurs, if any, on the particle surface, and a porous layer forms, in which the particles stick together almost in their initial dimension. The method is therefore first and foremost suitable for coating of substrates with low melting metals, such as tin and zinc.

### BRIEF SUMMARY OF THE INVENTION

The object of the invention is to provide a generic method for application of a coat onto a substrate, in which the required reaction energy, for example, for melting-on, breaking-up of atomic or molecular associations, &agglomeration and atomization of coating materials is reduced, so that a flawless coating is possible, for example, also with coating materials with higher melting temperatures.

The above object is achieved by a method for application of a coat onto a substrate comprising the steps of: generating a plasma beam of a tow temperature plasma by leading a working gas through an excitation zone; and, supplying platelet-shaped particles with a mean thickness between 10 and 50,000 nanometers and a form factor in the value range of 10 to 2000 are supplied into the plasma beam directed at the substrate.

Furthermore, the object of the invention is to provide a device with which the required reaction energy, for example, for melting-on, breaking-up of atomic or molecular associations, deagglomeration and atomization of coating materials is reduced, so that a flawless coating is possible, for example, also with coating materials with higher melting temperatures.

The above object is achieved by a device for application of a coat onto a substrate having a beam generator with an inlet for the supply of a flowing working gas; an outlet for a plasma beam led by the flowing working gas; an alternating voltage source or a pulsed direct voltage source which is connected to two electrodes of the beam generator, to form a discharge path along which the working gas is led; and, at least one teed opening of the beam generator is arranged, such that it discharging in an area of the discharge path and through which plate-shaped particles are supplied to the plasma beam,

Additionally, an object of the invention is to provide a coat where the required reaction energy, for example, for melting-on, breaking-up of atomic or molecular associations, deagglomeration and atomization of coating materials is reduced, so that a flawless coat is possible, for example, also with coating materials with higher melting temperatures.

The above object is achieved by a coat on a substrate, which includes platelet-shaped particles, which are at least partially fused with one another; and, the platelet-shaped particles have a mean thickness H between 10 and 50,000 nanometers and a form factor F in the value range of 10 to 2000 for application of the coat onto a substrate using a gas-led plasma beam of a low temperature plasma.

The platelet-shaped particles have, independently of the material, for example, a mean thickness H between 50-5,000 nm, but preferably between 100-2,000 nm.

The determination of the exact mean thickness H of the 10 platelet-shaped particles is carried out by means of the water coverage rate (spreading according to DM 55923) and/or by means of scanning electron microscopy (REM).

Below of a mean thickness H of the platelet-shaped particles of 10 nm, a flawless deposition of particles by means of the plasma beam is no longer guaranteed. In so far covering stratification is intended, the covering power of the coat is reduced due to the increasing transparency the platelet-shaped particles being that thin. The form factor is defined as the ratio of the mean longitudinal expansion D to the mean thickness H of the platelet-shaped particles. If platelet-shaped particles with a mean thickness H of 10 nm and a form factor 10 are used in the method according to the invention, the particles have for the mean longitudinal expansion D a value of 0.1 μm. If platelet-shaped particles with a mean thickness H of 50,000 nm and a form factor 10 are used in the method according to the invention, the particles have for the mean longitudinal expansion D a value of 500 μm. The intended mean longitudinal expansion of the particles strongly depends on the respective coating purpose. With a high form factor and at the same time a mean thickness H as low as possible, a better orientation of the platelet-shaped particles deposited onto the substrate is guaranteed. This is of particular interest for paint coatings of surfaces.

The feeding of the platelet-shaped particles into the plasma beam, for example, via the feed opening of a beam generator arranged immediately adjacent to the outlet for the plasma beam, does not necessarily have to take place in the gaseous state, but can also be carried out in the liquid or solid state. It is advantageous if, however, the feeding of the platelet-shaped particles is carried out by means of a carrier gas for the platelet particles. For generation of the mixture made up of the platelet-shaped particles and the carrier gas, the feed opening of the beam generator is connected via a line with a swirl chamber, The swirl chamber is designed as a closed container and is filled at most up to a maximum fill level with the platelet-shaped particles. The platelet-shaped particles are impinged through at least one gas inlet with a carrier gas under overpressure, for example, in a periodic sequence, where the swirled-up platelet-shaped particles flow together with the carrier gas as a mixture via at least one outlet arranged above the maximum fill level of the swirl chamber out of the container in the direction of the feed opening of the beam generator. The periodic impingement of the platelet-shaped particles in the swirl chamber with the carrier gas is performed with a frequency in the range of 1 Hz to 100 Hz. For example, the particles are impinged successively in time through several gas inlets with the carrier gas. The gas inlet(s) can directly discharge into the usually available stock of platelet-shaped particles. In addition to this preferred immediate blowing-in of the carrier gas into the particle, it is, however, also possible to arrange the gas inlets above the maximum fill level of the particles in the swirl chamber so that the carrier gas hits the surface of the particles.

The plasma beam is generated under a pressure in a pressure range of 0.5-1.5 bar, preferably however, under the conditions of the ambient pressure. One also speaks of an atmospheric plasma.

It showed completely surprisingly that, when using platelet-shaped particles, layers with excellent properties were generatable also with metals with higher melting points and non-metals. The higher specific surface of platelet-shaped particles, compared with spherical particles, is probably responsible for the very good properties.

The specific surface designates in this context the outer surface, with reference to the ground, which describes the surface per kilogram of the platelet-shaped particles and is defined as follows:

$${S}_{M} = \frac{surface}{weight} [ \frac{{m}^{2}}{kg} ]$$

For an ideal ball with the particle diameter d_{P}, the specific surface is accordingly:

$${S}_{M} = \frac{6}{{d}_{P} \times ρ} [ \frac{{m}^{2}}{kg} ]$$

It is known in the literature that nanoparticles have a reduced melting point compared with the macro-material. Such nanoparticles have a very large surface relative to their volume. This means that, for them, far more atoms are on the surface than for larger particles. Since atoms are available on the surface of less binding partners than atoms in the core of the particles, such atoms are very reactive. Therefore, they can interact considerably stronger with particles in their immediate environment as is the case for macro-particles. The platelet-shaped particles used in the invention have, compared with equally weighted spherical particles, a clearly increased surface. The surface of a spherical particle with a radius of 1 μm is, relative to an equally weighted platelet-shaped particle with a thickness of 0.01 μm, larger by the factor 30. Since essentially the surface of the particles react with the plasma, it is currently assumed that this enlarged surface results in a clearly better melting-on behavior of the particles.

Higher melt metals and ceramic particles can also be molten with lower energy with the method according to the invention in atmospheric low temperature-plasmas and deposited onto surfaces as a layer.

The enlarged surface of the platelet-shaped particles improves the binding between the deposited particles with one another as well as between the particles and the substrate.

A further advantage of the platelet-shaped particles is that their specifically larger surface compared with equally weighted spherical particles covers more efficiently the substrate to be coated. For example, for covering coats, the coating method can therefore be carried out with less coating material.

The use of platelet-shaped particles increases furthermore the process safety in such a way that the risk of explosion, which is present for very fine spherical particles, is reduced. Due to the platelet shape of the particles, a better conveyability of the particles in the plasma beam is further achieved.

Below a mean thickness H of the platelet-shaped particles of 10 nm, a flawless deposition of particles by means of the plasma beam is no longer guaranteed. In so fir covering stratification is intended, the covering power of the coat is reduced due to the increasing transparency the platelet-shaped particles being that thin.

The form factor is defined as the ratio of the mean longitudinal expansion D to the mean thickness H of the platelet-shaped particles. If platelet-shaped particles with a mean thickness of 10 nm and a form factor 10 are used in the method according to the invention, the particles have for the mean longitudinal expansion D a value of 0.1 μm. If platelet-shaped particles with a mean thickness H of 50,000 nm and a form factor 10 are used in the method according to the invention, the particles have for the mean longitudinal expansion D a value of 500 μm.

The intended mean longitudinal expansion of the particles strongly depends on the respective coating purpose. With a high form factor and at the same time a mean thickness H as low as possible, a better orientation of the platelet-shaped particles deposited onto the substrate is guaranteed. This is of particular interest for paint coatings of surfaces.

The thickness distribution represents an important parameter for the characterization of platelet-shaped particles according to the invention. Concerning the determination of the thickness distribution, there are in the prior art no measuring devices, which can determine this value easily. A determination is therefore carried out by default through the determination of the thickness of a statistically sufficiently large number of platelet-shaped particles with a REM—(scanning electron microscope); usually, approximately 50 to 100 particles are measured. To do so, the particles are, for example, dispersed in a varnish paint and the latter is subsequently applied onto a film. The film, coated with the varnish paint containing platelet-shaped particles, is subsequently cut with a suitable tool in such a way that the cut runs through the varnish paint. Subsequently, the prepared film is inserted into the REM in such a way that the direction of observation is vertical to the cutting surface. In this way, the particles are viewed to a large extent from the side, so that their thickness can be easily determined. The determination is performed in this context by default through marking the corresponding limits by means of a suitable tool like the software packages delivered by default with the REM apparatuses by the manufacturer. For example, the determination can be carried out using a REM apparatus of the Leo series by the manufacturer Zeiss (Germany) and the software Axiovision 4.6 (Zeiss, Germany). The thickness distribution of the platelet-shaped particles is not homogeneous. The thickness distribution is expediently represented in the form of a cumulative size distribution curve. The value h₅₀ of the thickness cumulative size distribution curve can be used as the average value. It says that 50% of all particles possess a thickness that is equal to this value and/or below this value. Alternatively, the thickness distribution can also be described with the value H₁₀ or H₉₀.

The platelet-shaped particles are, for example, fed into the plasma beam with the help of a carrier gas. The feeding of the platelet-shaped particles into the plasma beam must, however, not obligatorily take place in the gaseous state, but can also be in the liquid or solid state. The volumetric flow of the carrier gas is, for example, in a range of 1 l/min to 15 l/min and the pressure is in a range between 0.5 bar and 2 bar.

A homogeneous feeding of the platelet-shaped particles into a core zone of the plasma beam with a gas temperature of less than 900 degrees Celsius is performed, for example, transverse to the direction of propagation of the plasma beam.

Such platelet-shaped particles can be produced through different methods. Depending on whether the materials are metallic or non-metallic materials, such as ceramic or oxidic materials, different methods can be used for the production.

The production of metallic platelet-shaped particles is done, for example, by means of mechanical deformation of powders, for example, metal powders. The mechanical deformation is usually done in mills, in particular in agitator ball mills, edge mills, drum ball mill, rotary tube ball mill tube, etc.

The mechanical deformation is generally performed through wet grinding, i.e., through grinding of the powder together with a solvent, for example, an organic solvent like white-spirit, and in the presence of lubricant resp. wetting and/or dispersion additive such as oleic acid, stearic acid, etc. The grinding is carried out in the presence of grinding bodies, usually of grinding balls, where the ball diameter is usually in a range of 0.1 to 10 mm, but preferably of 0.2 to 4.0 mm. The grinding bodies are generally made of ceramic, glass or metal, such as steel. For example, steel balls are used as the grinding bodies. Such deformation is, for example, described in German Patent Application No. 10 2007 062 942 A1, the content of which is incorporated herein by reference.

In order to obtain metallic platelet-shaped particles, the powder used is, for example, size-classified and then mechanically deformed while obtaining platelet-shaped particles in a size distribution with a D50-value from a range of 0.5 to 200 μm. The classification can, for example, be carried out with infrasizers, cyclones, sieves and/or other known devices.

For this method, the metal particles can be measured in the form of a dispersion of particles. The scattering of the incident laser light is recorded in different spatial directions and evaluated according to the Fraunhofer diffraction theory by means of the CILAS apparatus according to the manufacturer's instructions. In this process, the particles are treated mathematically as balls. Thus, the determined diameters always relate to the equivalent spherical diameter, which is averaged over all spatial directions, independently of the actual shape of the metal particle. The size distribution is determined, which is calculated in the form of a volumetric mean value (with reference to the equivalent spherical diameter). This volumetrically averaged size distribution can inter alia be represented as a cumulative size distribution curve. The cumulative size distribution curve, in turn, is mostly characterized by way of simplification by certain characteristic values, for example, the value D50 or D90. A value D90 means that 90% of all particles are below the specified value. In other words, 10% of all particles are above the specified value. For a value D50, 50% of all particles are below and 50% of all particle above the specified value.

In one embodiment of the invention, the powder can be at first ground and then size-classified in order to obtain the platelet-shaped particles with a size distribution with a value D50 in a range of 1 to 150 μm. In another embodiment, the size distribution is between 1.5 μm and 100 μm; however, it is preferably between 2 μm and 50 μm.

The grade of purity of the metals is in this context preferably more than 70% by weight, more preferably more than 90% by weight, and even more preferably more than 95% by weight, each with reference to the total weight of the metal, the alloy or the mixture. For the production of the platelet-shaped particles, the metal, the metal mixture or the metal alloy can, for example, be molten under heat and subsequently transformed through atomization or through application onto rotary components into a powder. Metallic powders generated in such a way have, for example, a particle size distribution with a mean value (value D50) in the range of 1 to 100 μm, but preferably of 2 to 80 μm.

If non-metallic layers are to be applied onto substrates, non-metallic platelet-shaped particles are, for example, used in the coating process. In this case, completely oxidized or even only partially oxidized starting materials, for example, merely surface-oxidized starting materials, can be used. Such ones can be generated by targeted oxidation of metallic platelet-shaped particles. This oxidation can be carried out with all methods known to those skilled in the art. A further oxidation is possible in particular in oxygen-containing plasmas and, depending on the extent of energy coupling-in and according to the coating material, is done by default. By setting the oxygen content in the working gas, an oxidation can, if necessary, be controlled.

The metallic particles can be oxidized by gaseous phase oxidation and/or by liquid phase oxidation. For example, the oxidation is performed in a liquid or by means of combustion in a gas stream.

When carrying out the oxidation in a liquid phase or a liquid, this for example, happens in such a way that the powder is first distributed in the liquid phase or the liquid. This can be done with or without addition of auxiliary materials and with or without supply of energy. For example, the dispersion is performed without addition of auxiliary materials and while stirring. The liquid can be an inert liquid, which has no oxidizing effect, or a reactive liquid, which has an oxidizing effect and reacts with the metallic particles. After the dispersion, the oxidation either starts immediately or is started by the addition of an oxidant and/or oxidation catalyst and/or by temperature increase.

If the liquid is reactive and reacts with the metal, the oxidation can also begin already during the dispersion. It depends on the selected combination liquid/metallic powder and, if necessary, the presence of catalyst whether the oxidation reaction starts directly. For example, the oxidation is started by addition of an oxidant and/or oxidation catalyst. For example, for accelerating the oxidation reaction, the reaction mixture is warmed up during the oxidation. Examples of oxidants are sulfuric acid, potassium permanganate, hydrogen peroxide and further oxidants known to those skilled in the art. Examples of oxidation catalysts are metal, metal salts, acids and bases. For example, for the addition of acids and bases, the addition is performed in such a way that a pH value suitable for the oxidation reaction is adjusted in the reaction mixture. After the reaction has been started, it is maintained until the metal is available in an oxidation stage that is different from zero to at least 90% by weight, more preferably to at least 95% by weight, most preferably to at least 99% by weight, respectively with reference to the total weight of the metallic particles. In one embodiment, particles are available after the oxidation treatment completely as metal oxide.

The metal oxide content can be determined experimentally by means of methods known to those skilled in the art. During the oxidation reaction, the temperature can be increased, decreased or kept constant. In addition, further addition of one or more oxidants and/or oxidation catalysts can be done, where the oxidation process can be controlled. During the oxidation, additional chemical reaction can also be triggered, as required by addition of further reaction components, and/or further components, such as metals or metal oxides, can be incorporated in the resulting metal oxidic particles, for example, as doping.

By selecting these reaction parameters, the chemical and physical properties of the metal oxidic particles, their value as well as their morphology can be adjusted in a targeted manner. For example, the reaction parameters are adjusted in such a way that the oxidation product has properties, which facilitate the subsequent coating of substrate through introduction of the particle into a plasma and/or are advantageous for any intended application.

Preferred chemical reactions, which lead to oxidation of the metallic powder, are:

2Al+4H₂O→2AlOOH+3H₂

2Fe+2H₂O→2Fe(OH)+H₂

2Zn+H₂O→ZnO+H₂

2Cu+H₂O→Cu₂O+H₂

These oxidation reactions are provided as examples for illustrative purposes. The exact chemical reaction mechanism is often difficult to determine. Further possible reaction mechanisms of the oxidation of metals are described, for example, in the literature, such as in Holleman Wiberg, Lehrbuch der Anorganischen Chemie (Textbook of Inorganic Chemistry), 101st edition, de Gruyter Verlag, 1995.

After the oxidation, the metal-oxidic particles can be separated from the liquid in which the oxidation was performed. The separation can be done in such a way that the liquid is immediately removed from the reaction mixture. This can be done by methods known to those skilled in the art like thermal drying, for example, in an atmosphere with a reduced pressure. For example, the separation of the liquid is carried out after a first concentration of the solid body was performed by a simple process, in particular by means of filtration.

Following the separation, the metal oxide particles can optionally be subjected to tempering, i.e., an additional temperature treatment. By means of the tempering resp. this temperature treatment, for example, the chemical composition and/or the crystal structure of the previously metal-oxidic particles can be changed. The temperatures of such a temperature treatment are typically above 200° C., however, below the melting or decomposition temperature. The duration is typically in the range of a few minutes to a few hours. For example, through a temperature treatment, aluminum hydroxide, which was produced by means of reaction of aluminum metal powder in water, can be converted into aluminum oxide by heating-up to temperatures of more than 400° C. with fission of water. In the event of further temperature treatment in the range between 800° C. and 1300° C., the crystal structure of the aluminum oxide can be adjusted in a targeted manner. Therefore, for example, γ-Al₂₃ is converted, when heated to temperatures greater than 800° C., into γ-Al₂O₃.

In addition to the conversion of metallic particle into non-metallic particles, non-metallic platelet-shaped particles can also be produced directly. For example, platelet-shaped. particles made of crystalline, semi-crystalline or amorphous materials can be produced. For example, glass platelets are produced by pouring a beam of a molten glass into a rotating, cup-shaped container. Due to the rotation of the container, the molten glass is swirled out of the container in the form of a thin lamella. In this process, the melt solidifies, where platelet-shaped particles made of glass are formed.

Furthermore, non-metallic platelet-shaped particles can be generated through mechanical delamination of layer materials such as layer silicates.

The platelet-shaped particles can include different materials. In the case of metallic particles, the latter can, for example, be made of aluminum, zinc, tin, titanium, iron, copper, silver, gold, tungsten, nickel, lead, platinum, silicon, further alloys or mixtures thereof. In one embodiment, aluminium, copper, zinc and tin or alloys or mixtures thereof are advantageous. In the case of non-metallic particles, the latter can, for example, include oxides or hydroxides of the already mentioned metals or other metals; furthermore, the particles can include glass, layer silicates such as mica or bentonites. In addition, the particles can include carbides, silicates and sulfates. The extraction and preparation of suitable particles for the method can also take place in other ways (e.g., artificially by means of crystallization, pulling, etc., see breeding methods, or by using conventional mining and flotating and others). The particles can also be organic and inorganic salts. Furthermore, the particles can consist of pure or mixed homopolymers, copolymers, block polymers or pre-polymers resp. plastics or their mixtures, but also be organic pure or mixed crystals or amorphous phases.

The particles can also include mixtures of at least two materials. In one embodiment, the platelet-shaped particles have at least one, preferably enveloping coating.

The at least single coating can be, for example, a protective layer against corrosion, which is also designated as corrosion protection layer.

The platelet-shaped particles can, for example, be fitted with at least one metal oxide layer. The coating with metal oxides, metal hydroxides and/or metal oxide hydrates, is advantageously carried out by means of precipitation, by means of sol-gel methods or through wet chemical oxidation of the particle surface.

For metal oxide coating, oxides, hydroxides and/or oxide hydrates of silicon, aluminum, cerium, zirconium, yttrium, chromium and/or mixtures/admixtures thereof are preferably used.

In one embodiment, oxides, hydroxides and/or oxide hydrates of silicon and/or aluminum are used; however, oxides, hydroxides and/or oxide hydrates of silicon are preferred.

The layer thickness of the metal oxide layers, for example, of silicon oxide and/or aluminum oxide layers are in the range of 5 to 150 nm, preferably of 10 to 80 nm, and more preferably of 15 to 50 nm.

As the protective layer against corrosion, a protective layer made of organic polymers can also be applied. Polyacrylate and/or polymethacrylate coatings have proven to be very suitable, Of course, synthetic resin coatings consisting of, for example, epoxides, polyesters, polyurethanes, or polystyrenes and mixtures thereof can also be used.

Instead of or in addition to a coat including metal oxides and/or polymerized synthetic resins, the so-called passivation layers can also be applied. The mechanism of action of the passivation layer is complex. For inhibitors, it is mostly based on steric effects.

The inhibitors are usually added in low concentrations in the order of magnitude of 1% by weight to 15% by weight, with reference to the weight of the metal particles used.

For the inhibition, the following coating substances are preferably used: organically modified phosphonic acids resp, their esters of the general formula R—P(O) (OR1) (OR2), where: R=alkyl, aryl, alkyl-aryl, aryl-alkyl as well as alkyl ether, for example, ethoxylated alkyl ether and R1, R2=H, CnH2n+1, with n=1 to 12, but preferably 1-6, where alkyl can be branched or unbranched, respectively. R1 can be equal to or different from R2; and, is organic modified phosphonic acids and phosphonic esters of the general formula R—O—P(OR1) (OR2) with R=alkyl, aryl, alkyl-aryl, amyl-alkyl as well as alkyl ether, for example, ethoxylated alkyl ether, and R1, R2 CnH2n+1, with n=1 to 12, preferably 1-6, where alkyl can be branched or unhranched, respectively, R1 can be equal to or different from R2.

Likewise, pure, inorganic phosphonic acids or phosphonic esters or phosphoric acids or phosphoric esters or any mixtures of the same can be used.

Furthermore, the coating can include organically functionalized silanes, aliphatic or cyclic amines, aliphatic or aromatic nitro-compounds, heterocycles containing oxygen, sulfur and/or nitrogen, such as thiourea derivative, sulfur and/or nitrogen compounds of higher ketones, aldehydes and/or alcohols (fatty alcohols) and/or thiols, or mixtures of the same or comprise them. The passivating inhibitor layer can, however, also include the above-mentioned substances. Organic phosphonic acids and/or phosphoric acid esters or their mixtures are preferred. When using amine compounds, they have, for example, organic radicals with more than 6 C atoms. Above-mentioned amines are used, for example, together with organic phosphonic acids and/or phosphoric acid esters or their mixtures.

The passivation via corrosion protection barriers with chemical and physical protective effects is possible in diverse ways.

Passivating corrosion protection layers, which guarantee a good corrosion protection for platelet-shaped metallic particles, include silicon oxide, preferably silicon dioxide, chromium aluminium oxide, which is applied, for example, through chromatin methods, chromium oxide, zirconium oxide, cerium oxide, aluminium oxide, polymerized plastic resin(s), phosphate compounds, phosphite compounds or borate compounds or mixtures of the same.

Silicon dioxide layers and chromium aluminium oxide layers (chromatization) are advantageous. Cerium oxide, cerium hydroxide or oxide hydrate layers as well as aluminum oxide, aluminum hydroxide or aluminum oxide hydrate layers, such as described in German Patent No. 195 20 312 A1 are also advantageous.

The SiO₂ layers are, for example, produced by sol-gel methods with average layer thicknesses of 10-150 nm and preferably of 15-40 nm in organic solvents.

Furthermore, the coating mentioned can be combined so that, for example, in an embodiment, particles according to the invention have a coat made up of a SiO₂ layer with a subsequently applied layer made of functionalized silanes.

A packing density as high as possible of the deposited particles is equivalent to a layer, which is as much similar as possible to a closed, not particulate layer, and accordingly a. layer that corresponds to the ideal base material. A high packing density is achieved if the particles keep their form and structure to the largest extent possible during the coating process and are still present in particular in the resulting layer as single particles. The particles show such behavior as described if they consist of higher melting metals (melting point >500° C.) and non-metallic materials. The energy of the plasma activates such particles merely on their surface, where the shape of the particles as such is preserved in the layer resulting on the substrate.

The coats, which can be produced through the method according to the invention on the substrate made up of adult platelet-shaped particle that are at least partially fused with one another can be produced without binders between the coat and the substrate. Prerequisite for the production of coatings without binders between the layer and the substrate is the use of platelet-shaped particles made tip of a material, which melt at least partially under the action of the cold plasma beam on the surface, so that the platelet-shaped particles are fused partially with one another in the coating.

An advantageous device for the application of a coat made up of platelet-shaped particles is a device having a beam generator with an inlet for the supply of a flowing working gas and an outlet for a plasma beam led by the working gas, the beam generator has two electrodes that can be connected with an alternating voltage source or a pulsed direct voltage source to form a discharge path along which the working gas is conducted, the beam generator has a feed opening that discharges in the area of the discharge path and through which the plasma beam can be supplied with platelet-shaped particles.

The device is supplied through the inlet with ionizable gases, for example, pressurized air, nitrogen, argon, carbon dioxide or hydrogen as the working gas. The working gas is previously cleaned, so that it is oil-free and lubricant-free. The gas flow rate in an usual beam generator is between 10 and 70 l/min, in particular between 10 and 40 l/min, for a speed of the working gas between 10 and 100 m/s, in particular between 10 and 50 m/s.

The beam generator further includes two electrodes, for example, arranged coaxially at a distance from each other, which are connected with an alternating voltage source, for example, however a pulsed direct voltage source. The discharge path is formed between the electrodes. The pulsed direct voltage of the direct voltage source is preferably between 500 V and 12 kV. The pulse frequency is between 10 and 100 kHz, for example, however between 10 and 50 kHz.

Due to of the pulsed operation of the direct voltage source, it must be assumed that no thermal balance can result between the light electrons and the heavy ions. This results in a low temperature load of the platelet-shaped particles supplied in. The coating process with the beam generator according to the invention is, for example, controlled in such a manner that the plasma beam of the low temperature plasma in the core zone has a gas temperature of less than 900° C., for example, however of less than 500° C. (low temperature plasma).

Due to the fact that the feed opening discharges in the area of the discharge path between the electrodes of the beam generator, the platelet-shaped particles come into an area, in which direct plasma excitation is carried out by the plasma beam. Through this measure, the required reaction energy is kept as low as possible.

For example, the feed. opening is located immediately adjacent to the outlet for the plasma beam in the area of the discharge path.

If the supply nevertheless takes place below the outlet of the device, which is basically also possible, this results in merely an indirect plasma excitation by the gas-led plasma beam, which is less favorable in terms of energy.

The method according to the invention can be used for coating of a plurality of substrates. Substrates can be, for example, metals, wood, plastics or paper. The substrates can be provided in the form of geometrically complex shapes, like components or finished products, but also as a film or a sheet. The coats, which can be produced through the method according to the invention on the substrate made up of adult platelet-shaped particle that are at least partially fused with one another can be produced without binders between the coat and the substrate. Prerequisite for the production of coatings without binders between the layer and the substrate is the use of platelet-shaped particles made up of a material, which melt at least partially under the action of the cold plasma beam on the surface, so that the platelet-shaped particles are fused partially with one another in the coating.

The applications for the method according to the invention are likewise very diverse. With the method, optically and electromagnetically reflective or absorbing, electrically conductive, semiconducting or insulating layers, diffusion barriers for gases and liquids, sliding layers, wear protection layers and corrosion protection layers as well as layers for influencing the surface tension as well as layers for adhesion promotion can, for example, be produced.

Conductive layers, which are generated by means of the method, can for example, be used in order to generate heating conductor tracks. Furthermore, such conductive layers can also be used as s sheaths, as electric contacts, as sensor surface sand as antennas, for example, RFID (Radio Frequency Identification) antennas.

The coats can be applied over a large surface, so that they cover the substrate to a large extent (more than 70% of the surface of the substrate). However, the layers can also applied on small surfaces, for example, in the form of webs or as subareas, which cover less than 10% of the surface of the substrate. For example, for the application of coatings on small subareas of of the substrate, for example, for deposition of contacts, a relative movement is not necessary between the substrate and the beam generator during the coating. The layer can also be applied in the form of patterns, which are adapted to the desired functionality. The generation of geometric patterns can, for example, also be done by using masks.

An advantageous device for application of a coat made up of platelet-shaped particles is a device having a beam generator with an inlet for the supply of a flowing working gas and an outlet for a plasma beam led by the working gas, the beam generator has two electrodes that can be connected with an alternating voltage source or a pulsed direct voltage source to form a discharge path along which the working gas is conducted, the beam generator has a feed opening that discharges in the area of the discharge path and through which the plasma. beam can be supplied with platelet-shaped particles,

The device is supplied through the inlet with ionizable gases, for example, pressurized air, nitrogen, argon, carbon dioxide or hydrogen as the working gas. The working gas is previously cleaned, so that it is oil-free and lubricant-free. The gas flow rate in an usual beam generator is between 10 and 70 l/min, in particular between 10 and 40 l/min, for a speed of the working gas between 10 and 100 m/s, in particular between 10 and 50 m/s.

The beam generator further includes two electrodes, for example, arranged coaxially at a distance from each other, which are connected with an alternating voltage source, in particular however a pulsed direct voltage source. The discharge path is formed between the electrodes. The pulsed direct voltage of the direct voltage source is preferably between 500 V and 12 kV. The pulse frequency is between 10 and 100 kHz, for example, however between 10 and 50 kHz.

Due to of the pulsed operation of the direct voltage source, it must be assumed that no thermal balance can result between the light electrons and the heavy ions. This results in a low temperature load of the platelet-shaped particles supplied in. The coating process with the beam generator according to the invention is controlled, for example, in such a manner that the plasma beam of the low temperature plasma in the core zone has a gas temperature of less than 900° C., for example, however of less than 500° C. (low temperature plasma).

Due to the fact that the feed opening discharges in the area of the discharge path between the electrodes of the beam generator, the platelet-shaped particles come into an area, in which direct plasma excitation is carried out by the plasma beam. Through this measure, the required reaction energy is kept as low as possible.

For example, the feed opening is located immediately adjacent to the outlet for the plasma beam in the area of the discharge path. If the supply nevertheless takes place below the outlet of the device, which is basically also possible, this results in merely an indirect plasma excitation by the gas-led plasma beam, which is less favourable in terms of energy.

As already mentioned above, the feeding of the platelet-shaped particles is carried out preferably by means of a carrier gas for the platelet particles. For generation of the mixture made up of the platelet-shaped particles and the carrier gas, the feed opening of the beam generator is connected via a line with a swirl chamber. The swirl chamber is designed as a closed container and is filled at most up to a maximum fill level with the platelet-shaped particles. The platelet-shaped particles are impinged through at least one gas inlet with a carrier gas under overpressure, for example, in a periodic sequence, where the swirled-up platelet-shaped particles flow together with the carrier gas as a mixture via at least one outlet arranged above the maximum fill level of the swirl chamber out of the container in the direction of the feed opening of the beam generator.

The periodic impingement of the platelet-shaped particles in the swirl chamber with the carrier gas is performed with a frequency in the range of 1 Hz to 100 Hz. For example, the particles are impinged successively in time through several gas inlets with the carrier gas. The gas inlet(s) can directly discharge into the usually available stock of platelet-shaped particles. In addition to this immediate blowing-in of the carrier gas into the particle, it is, however, also possible to arrange the gas inlets above the maximum fill level of the particles in the swirl chamber so that the carrier gas hits the surface of the particles.

The present invention is illustrated by means of the subsequent exemplary embodiments, without, however, being limited to them.

Measurement Methods Used:

### Size-thickness Ratio:

The size-thickness-ratio of a particle sample from the embodiments illustrated was determined based on the evaluation of REM recordings. In this process, the longitudinal diameter was determined by means of Cilas 1064 and the thickness of a statistical number (at least 100) determined on particles, respectively, and the average value-thickness ratio was calculated through formation of the quotient from the longitudinal diameter to the thickness.

### EXAMPLE 1

### Preparation of Aluminium Powder

Approx. 2.5 tons of aluminum bars (metal) were continuous inserted and molten in an induction crucible furnace (from the company Induga, Cologne, Germany). In the so-called forehearth, the aluminum melt was available as a liquid at a temperature of about 720° C. A plurality of nozzles, which work according to an injector principle, were immersed in the melt and atomized the aluminum melt vertically upwards. The atomization gas was compressed in compressors (from the company Kaeser, Coburg, Germany) up to 20 bar and heated up in gas heaters up to approximately 700° C. The aluminum powder resulting after the pulverization/atomization solidified and cooled in the flight. The induction furnace war integrated in a closed installation. to The atomization was performed under inert gas (nitrogen). The deposition of the aluminum powder was performed first in a cyclone, wherein the pulverulent aluminium grit deposited there had a value D50 of 14-17 μm. A multi-cyclone was then used for further deposition, where the pulverulent aluminium powder deposited therein had a value D50 of 2.3-2.8 μm. The gas-solid separation was carried out in a filter (from the company Alpine, Thailand) with metal elements is (from the company Pall). While doing so, an aluminum powder with a d10 of 0.7 μm, (outside the range!) a (150 10 of 1.9 μm and a d90 of 3.8 μm were obtained as the finest fraction.

### EXAMPLE 2:

### Production of Metallic Platelet-Shaped Particles Through Grinding

In a pot mill (length: 32 cm, width: 19 cm), 4 kg of glass beads (diameter: 2 mm), 75 g of fine aluminum powder, 200 g of white spirit and 3.75 g of oleic acid were added. Subsequently, grinding was carried out for 15 h at 58 rpm. The product was separated through rinsing with white spirit from the grinding balls and subsequently sieved in a wet sieving process on a 25 μm sieve. The fine grain was freed to a great extent from white spirit via of a Nutsch filter (approx. 80% solid body content).

### EXAMPLE 3

### Production of Non-Metallic Platelet-Shaped Particles (Aluminum Hydroxide) Through Oxidation of Metallic Platelet-Shaped Particles (Aluminum)

In a 5 L glass reactor, 300 g of a deformed aluminium powder as described in Example 2 was dispersed in 1000 ml propanol (VWR, Germany) by stirring with a propeller stirrer. The suspension was heated up to 78° C. Subsequently, 5 g of an ammonia solution at 25% by weight (VWR, Germany) were added, After a short time, a massive formation of gas could be observed. Three hours after the first addition of ammonia, 5 g of ammonia solution at 25% by weight were also added. After three further hours, 5 g of ammonia solution at 25% by weight were again added. The suspension was further stirred overnight. On the next morning, the solid body was separated by means of a Nutsch filter and dried in the vacuum drying oven for 48 h at 50° C. A white powder was obtained. This powder was subsequently characterized. First, the particle size and the zeta potential were examined as a function of the pH. The pH setting was carried out by means of 1.0 M NaOH resp. 1.0 M HCl. Both for a low and also for a high pH value, the zeta potential exhibits a maximum and the particle diameter a minimum. A composition of approx. 33% by weight of boehmite (AlOOH) and 67% by weight of gibbsite (Al(OH)3) can be derived from an XRD analysis of the material.

### EXAMPLE 4

### Production of Non-Metallic Platelet-Shaped Particles (Aluminum Oxide) Through Temperature Treatment of 25 Non-Metallic Platelet-Shaped Particles (Aluminum Hydroxide)

500 g of a material produced according to Example 3 were heated for 10 minutes in a rotating tube furnace (Nabertherm, Germany) to 1100° C. 335 g of a white powder were obtained. This is was examined as described. In contrast to the uncalcinated material, the particle diameter is slightly larger and the zeta potential is positive in the entire pH range. The XRD analysis shows theta-Al₂O₃.

### BRIEF DESCRIPTION OF THE DRAWINGS

The nature and mode of operation of the present invention will now be more fully described in the following detailed description of the invention taken with the accompanying drawing figures, in which:

FIG. 1 is a schematic representation of an embodiment of a beam generator according to the invention; and,

FIG. 2 is an enlarged representation of the beam generator according to FIG. 1 in the area of the outlet.

### DETAILED DESCRIPTION OF THE INVENTION

At the outset, it should be appreciated that like drawing numbers on different drawing views identify identical, or functionally similar, structural elements of the invention. While the present invention is described with respect to what is presently considered to be the preferred aspects, it is to be understood that the invention as claimed is not limited to the disclosed aspects.

Furthermore, it is understood that this invention is not limited to the particular methodology, materials and modifications described and, as such, may, of course, vary. It is also understood that the terminology used herein is for the purpose of describing particular aspects only, and is not intended to limit the scope of the present invention, which is limited only by the appended claims.

Unless defined otherwise, all technical and scientific terms used herein have the same meaning as commonly understood to one of ordinary skill in the art to which this invention belongs. Although any methods, devices or materials similar or equivalent to those described herein can be used in the practice or testing of the invention, the preferred methods, devices, and materials are now described.

Beam generator 1 according to the invention for generation of plasma beam 2 of a low temperature plasma has two electrodes 4, 5 arranged in the flow of working gas 3 as well as voltage source 6 for generation of a pulsed direct voltage between electrodes 4, 5. First electrode 4 is carried out as a pin electrode, whereas second electrode 5 arranged at a distance thereto is formed as an annular electrode. The path between the tip of pin electrode 4 and ring electrode 5 forms discharge path 16.

Sheath 7 made of electrically conductive material is arranged concentrically with respect to pin electrode 4 and insulated against pin electrode 4. Working gas 3 is supplied through inlet 21 on the end face of beam generator 1 opposite annular electrode 5. Inlet 21 is located on sleeve 22 made of an electrically insulating material mounted at the end face on hollow cylindrical sheath 7 and holding pin electrode 4. On the opposite end face, sheath 7 tapers nozzle-spaced towards outlet 8 for plasma beam 2.

Feed opening 9 through which plasma beam 2 can be supplied with platelet-shaped particles 10 is located immediately adjacent to outlet 8 running in the direction of the axis of beam generator 1, transverse to its longitudinal extension. Feed opening 9 of beam generator 1 is connected for this purpose via line 12 with swirl chamber 11 in which platelet-shaped particles 10 are stored. Swirl chamber 11 is filled at most up to maximum fill level 13 with platelet-shaped particles 10. Below maximum fill level 13, inlet 23 for carrier gas 14, which is blown under an increased pressure compared with the ambient pressure into the particle stock, discharges into swirl chamber 11. Hereby, particles 10 are swirled up in the space above maximum fill level 13 and come via outlet 15, line 12 and feed opening 9 in discharge path 16 of beam generator 1.

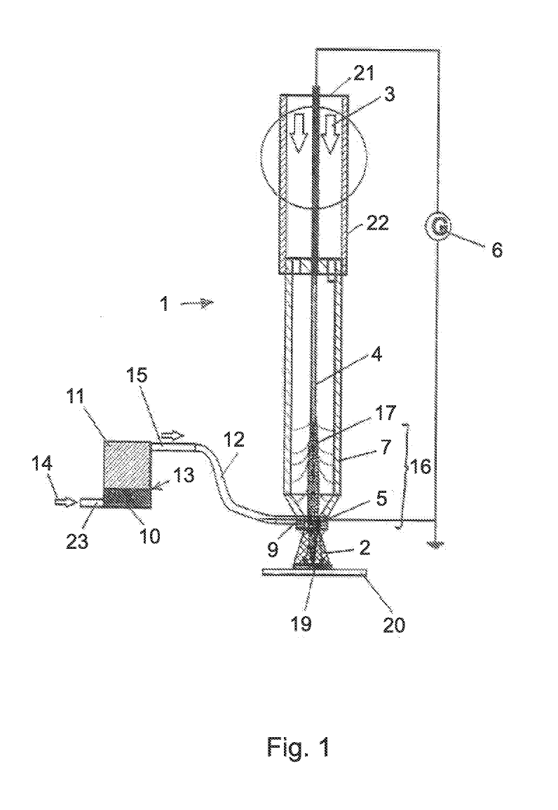

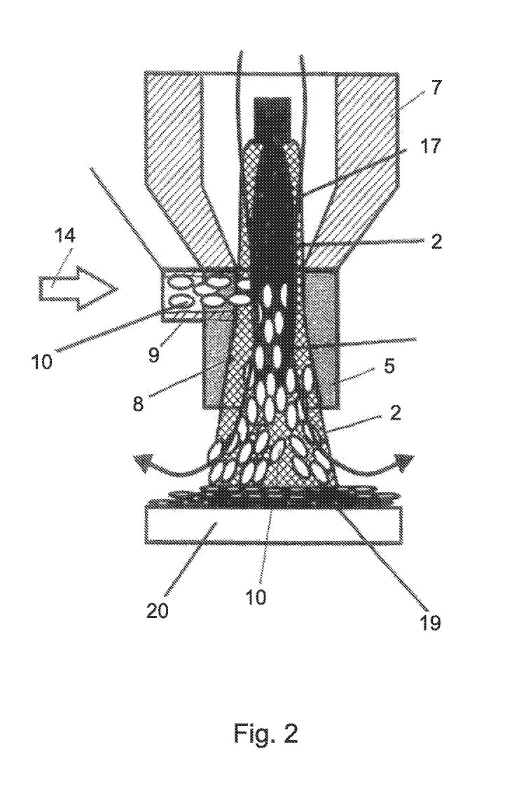

As can be seen, for example, from the enlargement in FIG. 2, platelet-shaped particles 10 get transverse to the direction of propagation of plasma beam 2 to core zone 17 of plasma beam 2, in which a temperature of less than 500° C. prevails (low temperature plasma). Voltage source 6 increases, during each pulse, the voltage applied between electrodes 4, 5 until to the ignition voltage for the formation of an electric arc between electrodes 4, 5 is available between electrodes 4, 5. Due to conductive sheath 7, it also comes to discharges in the direction of the inner lateral surface, as is indicated in FIG. 1 by the dotted lines. After reaching the ignition voltage, discharge path 16 between electrodes 4, 5 is conductive. Voltage source 6 is formed, for example, in such a manner that it generates a voltage pulse with an ignition voltage for the arc discharge and generates a pulse frequency, which causes the respective arcs between two consecutive voltage pulses to be cancelled. As a result, there is a pulsed gas discharge in plasma beam 2. The pulse frequency is, for example, in a range between 10 kHz and 100 kHz, and is 50 kHz in the embodiment represented. The voltage of voltage source 6 is at most 12 kV. Compressed air is used as working gas 3, where 40 l/min are supplied in the normal operating state.

If, by way of derogation from the embodiment represented, not only a punctual coat is to be generated on substrate 20 by means of beam generator 1, there is in one embodiment of the invention the option that plasma beam 2 and substrate 20 can be moved at least occasionally relative to one another during the application of the coat. The relative movement can be carried out by shifting substrate 20, for example on a table, which is movable in the horizontal plane. Alternatively, beam generator 1 is arranged in a XY shifting unit, which is movable in a plane that is at least parallel to substrate 20, so that the alternator can be moved with a defined speed relative to the substrate. Through the relative movement, webs or also full-surface coatings of substrate 20 can be generated.

Thus, it is seen that the objects of the present invention are efficiently obtained, although modifications and changes to the invention should be readily apparent to those having ordinary skill in the art, which modifications are intended to be within the spirit and scope of the invention as claimed. It also is understood that the foregoing description is illustrative of the present invention and should not be considered as limiting. Therefore, other embodiments of the present invention are possible without departing from the spirit and scope of the present invention.

What is claimed is:

1. A method for application of a coat onto a substrate comprising the steps of:
generating a plasma beam of a low temperature plasma by leading a working gas through an excitation zone; and,
supplying platelet-shaped particles with a mean thickness between 10 and 50,000 nanometers and a form factor in the value range of 10 to 2000 are supplied into the plasma beam directed at the substrate.

2. The method as recited in claim 1, wherein the platelet-shaped particles are supplied with the help of a carrier gas into the plasma beam.

3. The method as recited in claim 2, wherein the volumetric flow of the carrier gas is in a range of 1 l/min to 15 l/min and the pressure is in a range between 0.5 bar and 2 bar.

4. The method as recited in claim 1, wherein the plasma beam and the substrate can be moved at least occasionally relative to one another during the application of the coat.

5. The method as recited in claim 1, wherein the platelet-shaped particles are supplied into the plasma beam transverse to the direction of propagation of the plasma beam.

6. The method as recited in claim 1, wherein the plasma beam is generated with a gas temperature in a core zone of the plasma beam of less than 900° C.

7. The method as recited in claim 1, wherein the plasma beam is generated under an ambient pressure in a pressure range of 0.5-1.5 bar.

8. The method as recited in claim 1, wherein the plasma beam is generated through excitation of the working gas by means of an alternating voltage or a pulsed direct voltage.

9. The method as recited in claim 8, wherein the alternating voltage or the pulsed direct voltage is between 500 V and 15 kV and the frequency of the alternating voltage or the pulsed direct voltage is between 10 kHz to 100 kHz.

10. The method as recited in claim 1, wherein platelet-shaped particles, made of metal, are supplied in the plasma beam.

11. The method as recited in claim 10, wherein the metal is selected from the group consisting of aluminium, zinc, tin, titanium, iron, copper, silver, gold, tungsten, silicon or alloys or mixtures thereof.

12. The as recited in claim 10, wherein the metal is selected from the group consisting of oxides, carbides, hydroxides, carbonates, chlorides, fluorides, or mixtures thereof.

13. The method as recited in claim 1, wherein the platelet-shaped particles are additionally coated at least partially with a further layer.

14. The method as recited in claim 13, wherein the further layer is formed by a polymer.

15. The method as recited in claim 1, wherein the substrate is selected from the group consisting of metal, wood, plastics, glass, ceramic, biomaterials or paper.

16. A device for application of a coat onto a substrate, comprising:
a beam generator with an inlet for the supply of a flowing working gas;
an outlet for a plasma beam led by the flowing working gas;
an alternating voltage source or a pulsed direct voltage source which are connected two electrodes of the beam generator, to form a discharge path along which the working gas is led; and,
at least one feed opening of the beam generator is arranged such that it discharging in an area of the discharge path and through which plate-shaped particles are supplied to the plasma beam.

17. The device as recited in claim 16, wherein each feed opening is arranged immediately adjacent to the outlet for the plasma beam.

18. The device as recited in claim 16, wherein each feed opening of the beam generator is connected with a swirl chamber for generation of a mixture made up of the platelet-shaped particles and a carrier gas.

19. A coat on a substrate comprises:
platelet-shaped particles, which are at least partially fused with one another; and,
the platelet-shaped particles have a mean thickness H between 10 and 50,000 nanometers and a form factor F in the value range of 10 to 2000 for application of the coat onto a substrate using a gas-led plasma beam of a low temperature plasma.
